(19) United States
(12) Patent Application Publication
(10) Pub. No.: US 2006/0291163 A1
(43) Pub. Date: Dec. 28, 2006

(54) Plasma display apparatus

(76) Inventor: Yeung Ki Kim, Yongin-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/493,328

(22) Filed: Jul. 25, 2006

(30) Foreign Application Priority Data
Jun. 26, 2005 (KR) 10-2005-0067978

(51) Int. Cl. H05K 7/20; H01J 61/52

(52) U.S. Cl. 361/695; 313/46

(57) ABSTRACT

A plasma display apparatus having a chassis base made of a synthetic resin is disclosed. In the plasma display apparatus, the chassis base has a supporting structure (including protruding portions) formed on a surface thereof so as to support the plasma display panel, thereby preventing the plasma display panel from be damaged by an exterior force. According to one embodiment of the invention, since the chassis base supports the plasma display panel more stably by way of the supporting structure, it is possible to prevent the plasma display panel from being damaged by an external force.

### RELATED APPLICATION

This application takes priority under 35 U.S.C. §119(a) from Korean application no. 2005-0067978, filed on Jul. 26, 2005, which is incorporated by reference in its entirety.

### BACKGROUND OF THE INVENTION

1. Field of the Invention

The present invention relates to a plasma display apparatus, and more particularly to a plasma display apparatus which has a chassis base made from synthetic resin and a supporting structure formed on a surface of the chassis base so as to support the plasma display panel, thereby preventing the plasma display panel from being damaged by an exterior force.

2. Description of the Prior Art

In general, a plasma display apparatus refers to a flat display device which uses a plasma display panel to display images. The plasma display apparatus includes two substrates having discharging electrodes on respectively opposite faces thereof, and discharging gases injected into defined and closed discharging spaces between the substrates. When a predetermined amount of electricity is applied to the discharging electrode, ultra-violet radiation is generated in the discharging spaces and excites a fluorescent substance layer so that the fluorescent substance emits light. Thus, the plasma display apparatus can display images using the light emitted from the fluorescent substance.

Typically, the chassis base of a plasma display apparatus is made of aluminum. Recently, it has been proposed to make a chassis base of a steel plate having strength higher than that of the aluminum, in order to reduce a thickness of the plasma display apparatus. In the case where the chassis base is made of the steel plate, the chassis base can have a thickness which is thinner than that of the chassis base made of the aluminum.

The chassis base is made from the aluminum alloy or the steel plate, of which a surface is flat. It is usual to use an adhesive member in order to attach the chassis base to the plasma display panel as well as to allow the chassis base to support the plasma display.

However, in the case of using the conventional chassis base which is made of an aluminum alloy or steel plate as described above, there are disadvantages in that the total weight of the plasma display apparatus increases due to the weight of metal material. Therefore, the use of synthetic resin for a chassis base has been proposed in order to reduce the weight of the chassis base. On the other hand, in the case where a chassis base is made from the synthetic resin, the chassis base is attached to the plasma display panel by means of the adhesive members so as to support the plasma display panel.

At this time, the adhesive members are restrictedly used only for some portions of surfaces of the plasma display panel and the chassis base. Therefore, when external impact is applied to the plasma display panel, the impact is not transferred to another structural elements such as the chassis base, but distributed over the whole surface of the plasma display panel. Accordingly, there is a problem in that the plasma display panel may be damaged.

### SUMMARY OF THE INVENTION

One aspect of the present invention provides a plasma display apparatus which has a chassis base made from synthetic resin and including a supporting structure formed on a surface thereof so as to support the plasma display panel, thereby preventing the plasma display panel from being damaged by an exterior force.

Another aspect of the present invention provides a plasma display apparatus which comprises: a plasma display apparatus which comprises: a plasma display panel including a front panel and a rear panel, a chassis base which is made from synthetic resin, for supporting the plasma display panel, a driving circuit portion including circuit boards mounted on a rear surface of the chassis base and a supporting structure formed on a front surface of the chassis base so as to support the plasma display panel.

The chassis base may be made from polyester resin, polycarbonate resin, or epoxy resin.

In one embodiment, the supporting structure of the chassis base has a height which is identical to or similar to a thickness of double-sided tapes used for attaching the plasma display panel to the chassis base, and is in contact with the rear surface of the plasma display panel at it top portion so as to support the plasma display panel.

Another aspect of the invention provides a plasma display apparatus, comprising: a chassis base including first and second surfaces opposing each other, wherein the first surface of the chassis base is configured to support a plasma display panel and a plurality of protruding portions formed on the first surface of the chassis base so that the protruding portions extend toward the plasma display panel.

### BRIEF DESCRIPTION OF THE DRAWINGS

Embodiments of the claimed invention will be described in conjunction with the accompanying drawings.

FIG. 1 is a perspective view showing a plasma display apparatus according to one embodiment of the present invention;

FIG. 2 is a sectional view showing the plasma display apparatus according to one embodiment of present invention, taken along a line II-II in FIG. 1.

FIG. 3 is a perspective view showing an example of a chassis base adopted in the plasma display apparatus according to one embodiment of the present invention.

FIG. 4 is a perspective view showing another example of a chassis base adopted in the plasma display apparatus according to another embodiment of the present invention.

### DETAILED DESCRIPTION OF THE PREFERRED EMBODIMENTS

Hereinafter, embodiments of the present invention will be described in detail with reference to the accompanying drawings.

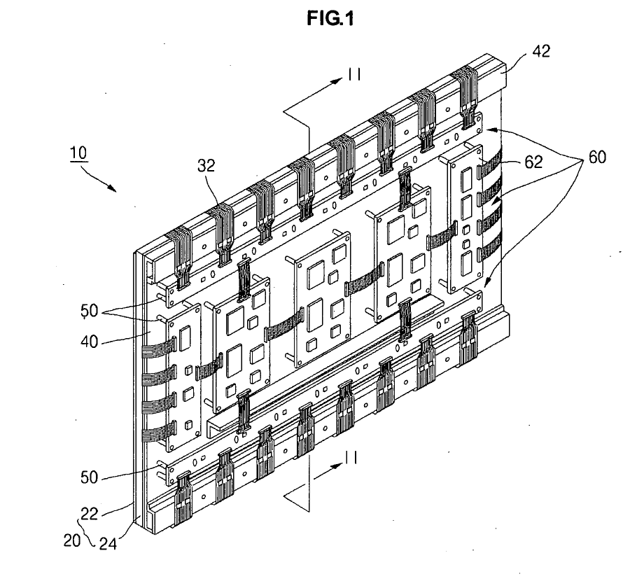

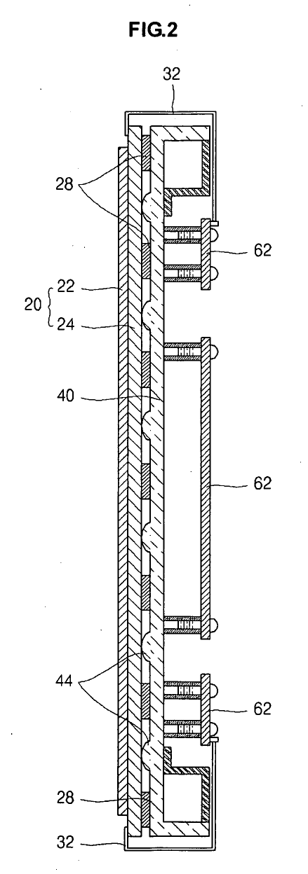

FIG. 1 is a perspective view showing a plasma display apparatus according to one embodiment of the present invention, and FIG. 2 is a sectional view showing the plasma display apparatus according to one embodiment of present invention, taken along a line II-II in FIG. 1. In one embodiment, as shown in FIGS. 1 and 2, the plasma display apparatus 10 includes a plasma display panel 20, a chassis base 40 of which the plasma display panel 20 is attached to a front surface and supported by the chassis base 40, and a driving circuit portion 60 having circuit boards 62 mounted on a rear surface of the chassis base 40 which is opposite to the surface of the chassis base 40 facing the plasma display panel 20. The apparatus 10 also includes a signal transmission member 32, such as tape carrier package, which electrically connects the panel 20 and the driving circuit portion 60. Reference numeral 42 in FIG. 1 represents a reinforcement member or a chassis bending portion. The plasma display panel 20 includes a front panel 22 and a rear panel 24, in which voltage applied to electrodes formed in the plasma display panel 20 causes gases filled between the front and rear panels 22 and 24 to discharge electricity and to radiate ultra-violet radiation which then collides against a fluorescent substance layer and makes the fluorescent substance layer emit light. As a result, the plasma display apparatus can display images. Especially, the plasma display panel 20 includes discharging cells (not shown) which are defined by the front panel 22, the rear panel 24, and barriers and in which a discharge occurs, the discharging gases which are filled in the discharging cells so as to discharge the electricity, the fluorescent substance layer coated on a surface of each discharging cell, and electrodes (not shown) subjected to the voltage. In the plasma display apparatus 20, voltage of direct or alternating current applied to the electrodes causes the discharge into the discharging cells, and then the ultra-violet radiation emitted from the discharging gases excites the fluorescent substance to generate visual light, thereby displaying the images.

In one embodiment, the chassis base 40, to which the plasma display panel 20 is fixed, is made from synthetic resin, in which a conductive mesh or conductive metal plate may be formed as a grounding member. In one embodiment, the chassis base 40 is made from any one resin selected from polyester, polycarbonate, or epoxy resin.

In one embodiment, the chassis base 40 is made by way of an injection molding method and has a supporting structure 44 formed on a front surface thereof. In one embodiment, one of dies used for injection-molding the chassis base 40 has a structure for forming the supporting structure 44.

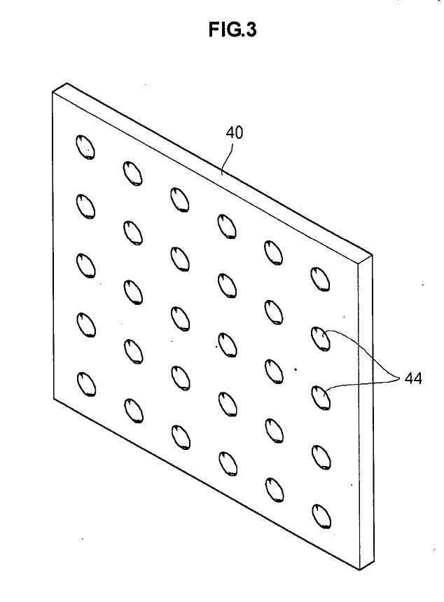

FIG. 3 is a perspective view showing an example of a chassis base adopted in the plasma display apparatus according to one embodiment of the present invention.

In one embodiment, as shown in FIG. 3, the supporting structure 44 includes a plurality of protuberances having a semi-circular sectional shape and may be formed to have a height which is substantially identical to or smaller than the thickness of double-sided tape which attaches the plasma display panel 20 to the chassis base 40. In one embodiment, the supporting structure 44 is formed to have the height enough to come in contact with the rear surface of the plasma display panel when the chassis base 40 is attached to the rear surface of the plasma display panel 20 by pieces of the double-sided tape. In another embodiment, only part of the plurality of protuberances contacts the rear surface of the plasma display panel.

In one embodiment, when the chassis base 40 has a height smaller than the thickness of the double-sided tape, the height of the chassis base 40 is advantageous to approach the thickness of the double-sided tape, so that the rear surface of the plasma display panel 20 attached to the chassis base 40 by the pieces of the double-sided tape interposed between them comes into contact with the top portion of the supporting structure 44.

Since the supporting structure 44 having the semi-circular sectional-shaped protuberances comes in contact with the rear surface of the plasma display panel 20 at the top portion thereof, the plasma display panel is supported by the supporting structure 44 in such a manner that it is in contact at various points with the protuberances.

Further, since the chassis base 40 is joined to the plasma display panel by means of the pieces of the double-sided tape 28, it is possible to decide positions of the pieces of the double-sided tape 28 on the chassis base 40 before the joining process. In one embodiment, when the positions of the pieces of the double-sided tape are decided, it preferred that the position of the supporting structure 44 is not allowed to overlap with the adhering position of the double-sided tape.

When the plasma display panel 20 is joined to the chassis base 40 by means of the double-sided tape 28, the rear surface of the plasma display panel 20 is in contact with the top portion of the supporting structure 44 integrally formed with the front surface of the chassis base 40. Thus, even though external force is applied to the plasma display panel 20, the plasma display panel 20 is supported by the supporting structure 44 so as to avoid the movement thereof, thereby preventing the panel 20 from being damaged or broken.

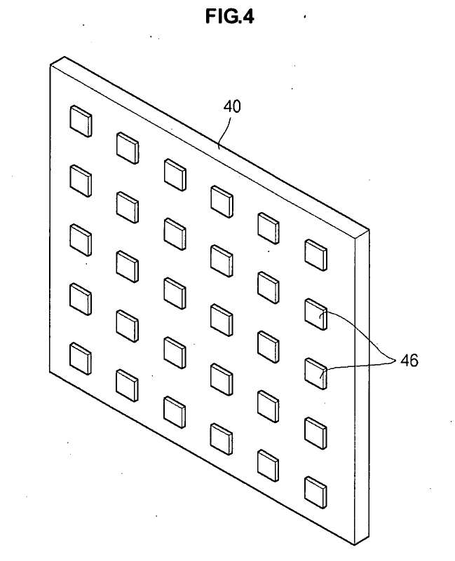

FIG. 4 is a perspective view showing another example of a chassis base adopted in the plasma display apparatus according to another embodiment of the present invention. In one embodiment, as shown in FIG. 4, a supporting structure 46 includes protuberances having a cubical shape, which are formed on the front surface of the chassis base 40. In one embodiment, the supporting structure 46 has substantially the same height as the thickness of the double-sided tape. When the plasmas display panel 20 is attached to the chassis base 40 by means of the double-sided tape, the plasma display panel 20 can be supported by the supporting structure 46 in the state of a surface contact with the supporting structure. Accordingly, since chassis base 40 supports the plasma display panel 20 more stably, it is possible to prevent the plasma display panel from being damaged by an external force. In another embodiment, the protuberances may have shapes different from those shown in FIGS. 3 and 4, for example, cylindrical or other polygonal shapes. In another embodiment, the protuberances may include different shapes, e.g., cubical shape and semi-circular sectional shape together formed on the chassis base.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A plasma display apparatus, comprising:
a plasma display panel;
a chassis base which is made of a synthetic resin, wherein the chassis base includes first and second surfaces opposing each other, and wherein the first surface of the chassis base is configured to support the plasma display panel;
a driving circuit portion including circuit boards mounted on the second surface of the chassis base; and
a supporting structure formed on the first surface of the chassis base so as to further support the plasma display panel.

2. The plasma display apparatus as claimed in claim 1, wherein the supporting structure includes a plurality of protuberances formed at a predetermined distance from one another.

3. The plasma display apparatus as claimed in claim 1, wherein the supporting structure is formed such that the protuberances are embossed.

4. The plasma display apparatus as claimed in claim 1, wherein the supporting structure has substantially the same height as the thickness of a double-sided tape configured to attach the plasma display panel to the chassis base.

5. The plasma display apparatus as claimed in claim 1, wherein the supporting structure has a sufficient height to come in close contact with a rear surface of the plasma display panel.

6. The plasma display apparatus as claimed in claim 4, wherein the supporting structure includes a plurality of protuberances having a semi-circular sectional shape, so that each of protuberances is in point contact with a rear surface of the plasma display panel.

7. The plasma display apparatus as claimed in claim 4, wherein the supporting structure includes a plurality of protuberances having a quadrangular sectional shape, so that each of protuberances is in surface contact with a rear surface of the plasma display panel.

8. The plasma display apparatus as claimed in claim 1, wherein the chassis base is attached to the plasma display panel by a plurality of pieces of double-sided tape.

9. The plasma display apparatus as claimed in claim 8, wherein the supporting structure includes a plurality of protuberances which are located at gaps between the pieces of the double-sided tape on the first surface of the chassis base.

10. The plasma display apparatus as claimed in claim 1, wherein the synthetic resin is one of the following: polyester resin, polycarbonate resin, and epoxy resin.

11. The plasma display apparatus as claimed in claim 1, wherein at least part of the supporting structure contacts the plasma display panel.

12. A plasma display apparatus, comprising:
a chassis base including first and second surfaces opposing each other, wherein the first surface of the chassis base is configured to support a plasma display panel; and
a plurality of protruding portions formed on the first surface of the chassis base so that the protruding portions extend toward the plasma display panel.

13. The plasma display apparatus as claimed in claim 12, further comprising a plurality of adhesive elements spaced apart with respect to each other and formed between the plasma display panel and the chassis base so as to couple the panel and chassis base, wherein the plurality of protruding portions are formed in the gaps between adjacent adhesive elements.

14. The plasma display apparatus as claimed in claim 12, wherein at least part of the plurality of protruding portions contacts the plasma display panel.

15. The plasma display apparatus as claimed in claim 12, wherein at least part of the plurality of protruding portions has a semicircular sectional shape.

16. The plasma display apparatus as claimed in claim 12, wherein at least part of the plurality of protruding portions has a quadrangular sectional shape.

17. The plasma display apparatus as claimed in claim 12, wherein the chassis base is made of resin material.
